(19) United States
(12) Patent Application Publication
(10) Pub. No.: US 2025/0089432 A1
(43) Pub. Date: Mar. 13, 2025

(54) PEROVSKITE QUANTUM DOT-BASED INDOOR PHOTOVOLTAIC CELL AND MANUFACTURING METHOD THEREOF

(71) Applicant: KOREA UNIVERSITY RESEARCH AND BUSINESS FOUNDATION, Seoul (KR)

(72) Inventors: Jae Won SHIM, Seoul (KR); Seon Joong KIM, Seoul (KR)

(21) Appl. No.: 18/806,297

(22) Filed: Aug. 15, 2024

(30) Foreign Application Priority Data
Sep. 12, 2023 (KR) 10-2023-0121003

(51) Int. Cl. H10K 30/50; H10K 30/40; H10K 30/85; H10K 85/60

(52) U.S. Cl. CPC H10K 30/50; H10K 30/40; H10K 30/85; H10K 85/615; H10K 85/6572

(57) ABSTRACT

Disclosed are a perovskite quantum dot-based indoor photovoltaic cell and a manufacturing method thereof. A perovskite quantum dot-based indoor photovoltaic cell includes a transparent lower electrode layer through which indoor light passes; a photoactive layer that generates excitons by the indoor light and separates the excitons into positive and negative charges; and an upper electrode layer that absorbs the negative charge, wherein the photoactive layer is formed of a perovskite quantum dot.

### CROSS-REFERENCE TO RELATED APPLICATION

This application claims under 35 U.S.C. § 119(a) the benefit of Korean Patent Application No. 10-2023-0121003 filed on Sep. 12, 2023, the entire contents of which are incorporated herein by reference.

### BACKGROUND

### (a) Technical Field

The present invention relates to a perovskite quantum dot-based indoor photovoltaic cell and a manufacturing method thereof.

### (b) Background Art

Indoor photovoltaic cells have the disadvantage of making it difficult to guarantee practical use as a power supply for indoor applications such as Internet of Things (IoT) due to the limited emission wavelength range of indoor light sources and the limited number of carriers. Therefore, it is very important to improve power conversion efficiency of the indoor photovoltaic cells.

In this context, perovskite-based indoor photovoltaic cells are attracting attention as they have superior power conversion efficiency compared to other photoactive material-based indoor photovoltaic cells. However, despite high efficiency, the perovskite-based indoor photovoltaic cells face serious obstacles in a commercialization process due to low moisture stability.

### SUMMARY OF THE DISCLOSURE

The present invention is to provide a perovskite quantum dot-based indoor photovoltaic cell and a manufacturing method thereof.

In addition, the present invention is to provide a perovskite quantum dot-based indoor photovoltaic cell capable of increasing the lifespan of charge carriers and improving charge transport performance by performing surface passivation on perovskite quantum dots to reduce a trap state of the perovskite quantum dots, and a manufacturing method thereof.

In addition, the present invention is to provide a perovskite quantum dot-based indoor photovoltaic cell capable of improving moisture stability of an indoor photovoltaic cell by increasing moisture stability of perovskite quantum dots due to hydrophobicity of a carbazole group of 2PACz through surface passivation using 2PACz for the perovskite quantum dots, and a manufacturing method thereof.

According to an aspect of the present invention, there is provided a perovskite quantum dot-based indoor photovoltaic cell.

According to an embodiment of the present invention, an indoor photovoltaic cell includes: a transparent lower electrode layer through which indoor light passes; a photoactive layer that generates excitons by the indoor light and separates the excitons into positive and negative charges; and an upper electrode layer that absorbs the negative charge, wherein the photoactive layer is formed of a perovskite quantum dot.

The photoactive layer may be formed by forming the perovskite quantum dot into a thin film of a predetermined thickness using an LBL deposition method and then performing a surface passivation process.

A surface passivation process may be performed to replace a long-chain insulating organic ligand on the surface of the perovskite quantum dot with 2-(9H-carbazol-9-yl)ethyl phosphate (2PACz) conjugated with a short chain.

The indoor photovoltaic cell may further include a charge transport layer between the photoactive layer and the upper electrode layer, wherein the charge transport layer is formed of Spiro-OMeTAD.

According to another aspect of the present invention, there is provided a method of manufacturing an indoor photovoltaic cell.

According to an embodiment of the present invention, a method of manufacturing an indoor photovoltaic cell includes: (a) forming a transparent lower electrode through which indoor light passes on a substrate; (b) generating excitons by the indoor light by depositing a perovskite quantum dot on a transparent lower electrode to a predetermined thickness using an LBL deposition method, and forming a photoactive layer separating the excitons into positive and negative charges; and (c) forming an upper electrode layer on the photoactive layer to absorb the negative charge, wherein in the step (b), the perovskite quantum dots are deposited to the predetermined thickness and then a surface passivation process is performed to form the photoactive layer.

According to an embodiment of the present invention, by providing the perovskite quantum dot-based indoor photovoltaic cell and the manufacturing method thereof, the surface passivation is performed on the perovskite quantum dot to reduce the trap state of the perovskite quantum dot, thereby increasing the lifespan of the charge carrier and improving the charge transport performance.

In addition, according to the present invention, by increasing the moisture stability of the perovskite quantum dots due to the hydrophobicity of the carbazole group of 2PACz through the surface passivation using 2PACz for the perovskite quantum dots, it is also possible to improve the moisture stability of the indoor photovoltaic cells.

### BRIEF DESCRIPTION OF DRAWINGS

FIG. 1 is a diagram illustrating a perovskite quantum dot-based indoor photovoltaic cell structure according to an embodiment of the present invention.

FIG. 2 is a view illustrating a scanning electron microscope photograph of the perovskite quantum dot-based indoor photovoltaic cell according to an embodiment of the present invention.

FIG. 3 is a schematic diagram of a perovskite quantum dot surface according to an embodiment of the present invention.

FIG. 4 and FIG. 5 are a diagram illustrating FT-IR analysis results, X-ray rotation analysis results, absorbance, emission spectrum, and time-resolved fluorescence spectroscopy results before and after surface passivation according to an embodiment of the present invention.

FIG. 6 and FIG. 7 are a diagram illustrating the results of highest efficiency of indoor photovoltaic cell performance specified in outdoor lighting depending on whether the surface passivation is performed on the perovskite quantum dot according to an embodiment of the present invention, the results of highest efficiency of indoor photovoltaic cell performance in indoor lighting, and external quantum efficiency (EQE) spectrum results.

FIG. 8 and FIG. 9 are a diagram illustrating the relationship between photocurrent density (Jₚₕ) and effective voltage (V_{eff}) according to outdoor and indoor light irradiation environments depending on whether the surface passivation is performed on the perovskite quantum dot according to an embodiment of the present invention, electrochemical impedance spectroscopy (EIS) measurement results, space charge limit current analysis results, and results of analyzing changes in V_{OC} according to light intensity in outdoor and indoor light irradiation environments and analyzing changes in safety of an indoor photovoltaic cell.

### DETAILED DESCRIPTION

Singular forms as used herein include plural forms unless the context clearly indicates otherwise. The term “including”, “include’, or the like, as used herein is not to be construed as necessarily including all of several components or several steps described herein, and it is to be construed that some of these components or steps may not be included or additional components or steps may be further included. In addition, the terms “ . . . unit”, “module”, and the like, as used herein refer to a processing unit of at least one function or operation and may be implemented as hardware or software or a combination of hardware and software.

Hereinafter, embodiments of the present invention will be described in detail with reference to the accompanying drawings.

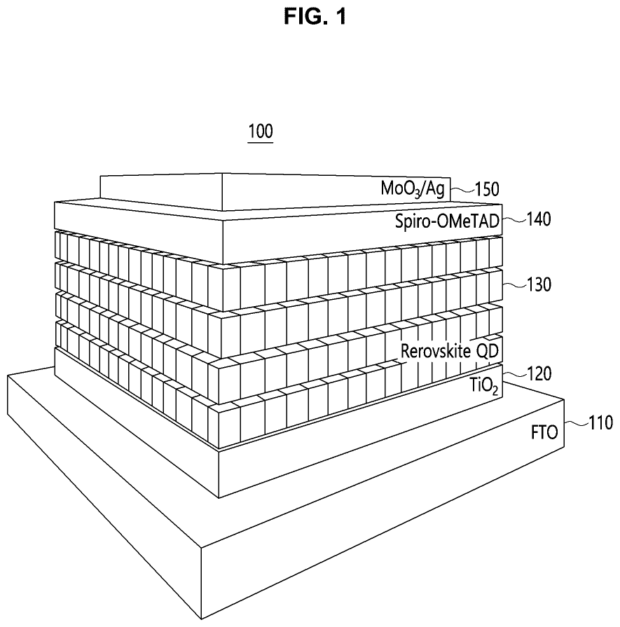

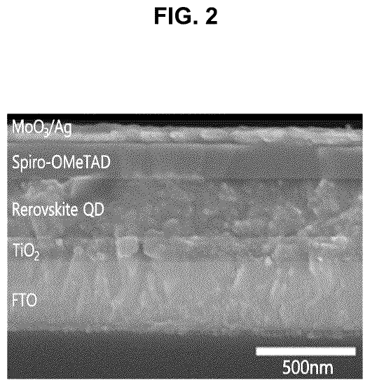

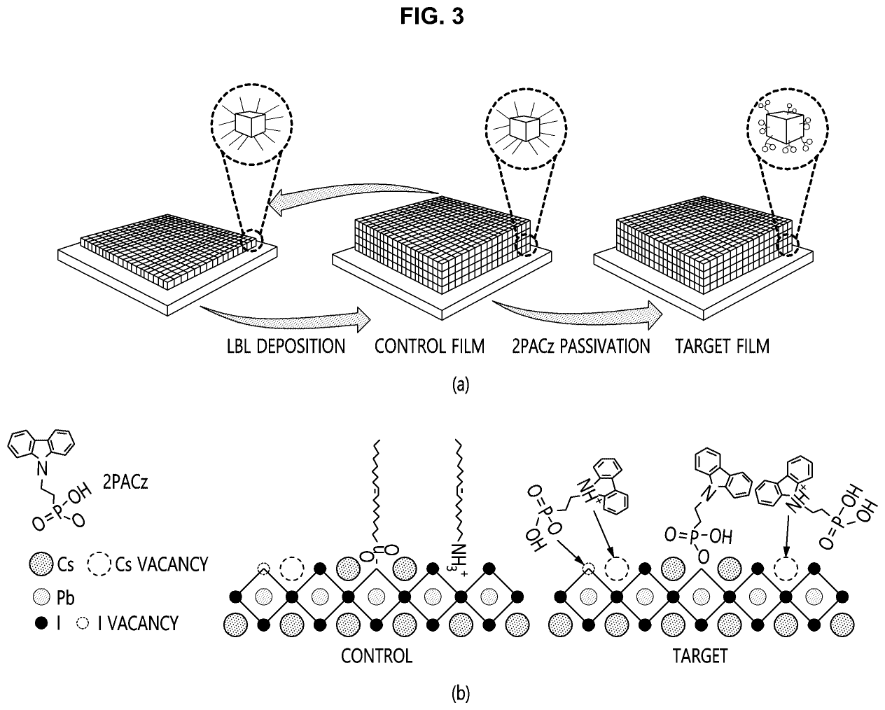

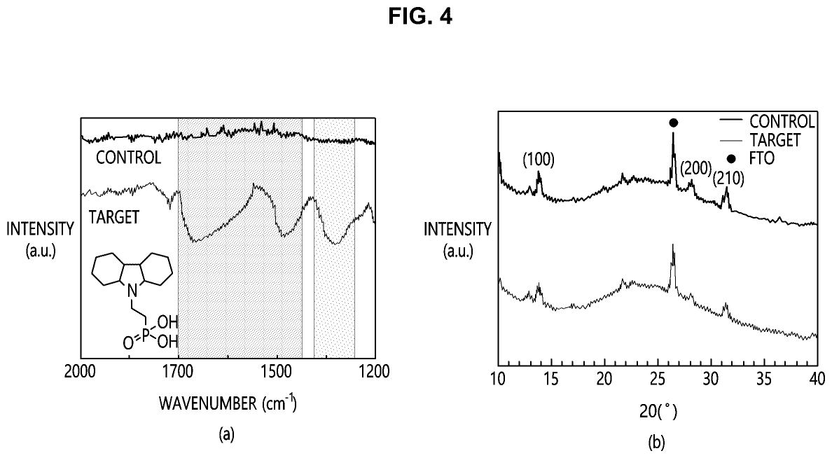

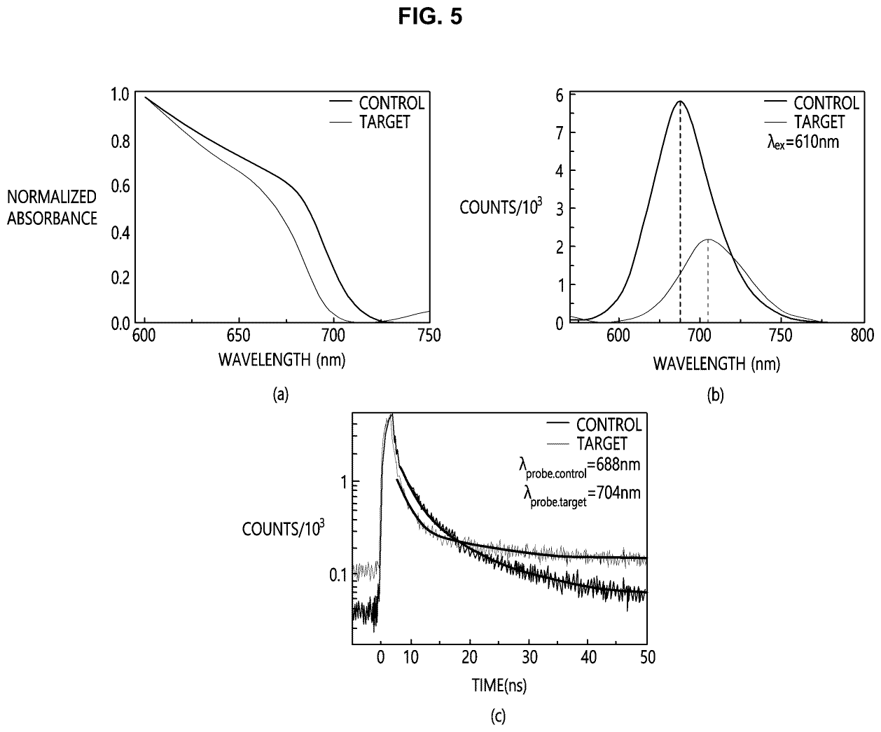

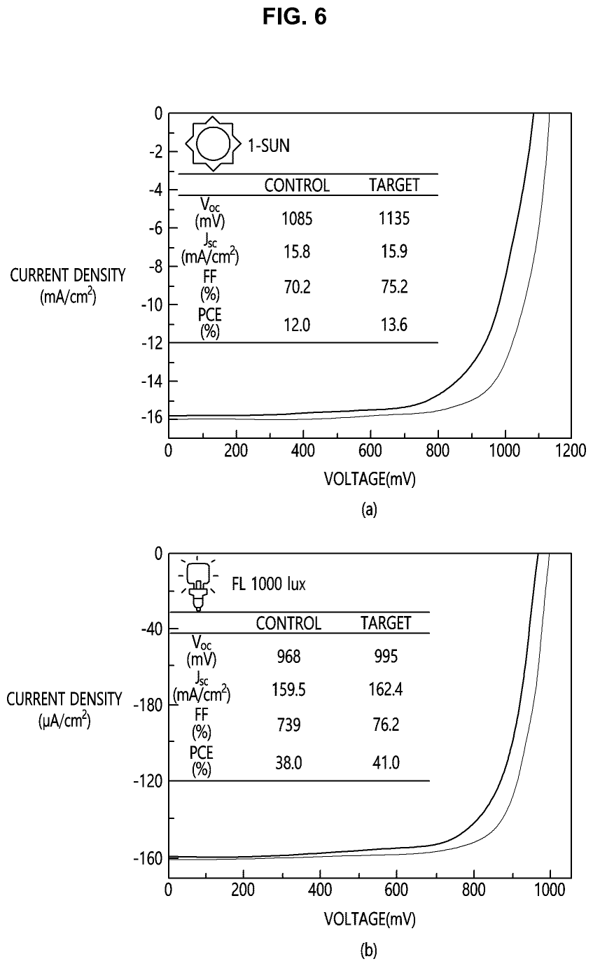

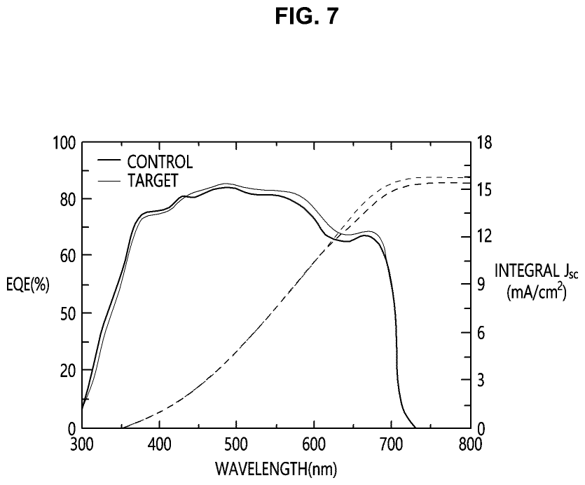

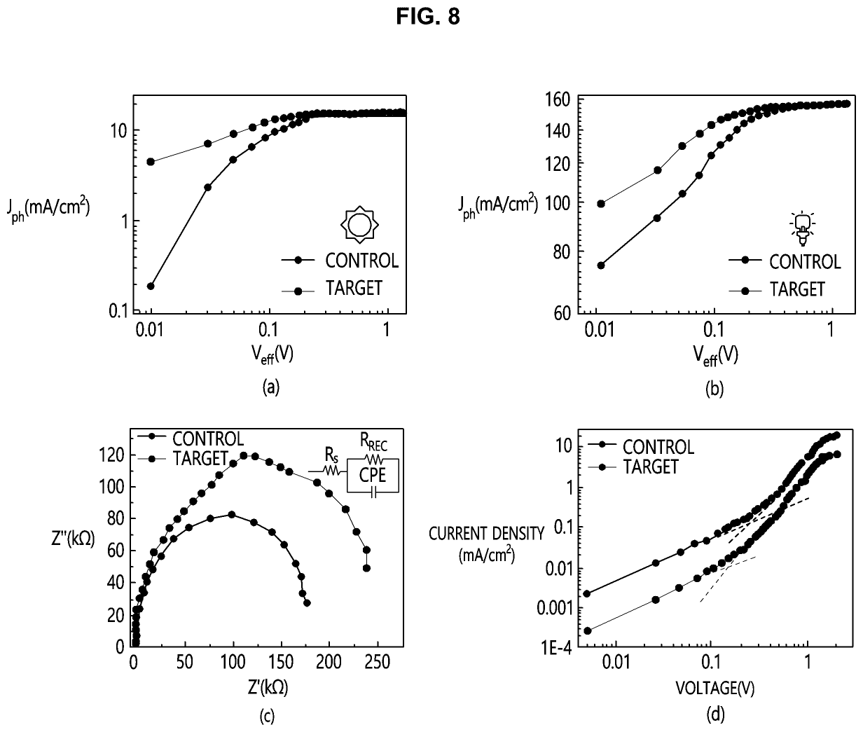

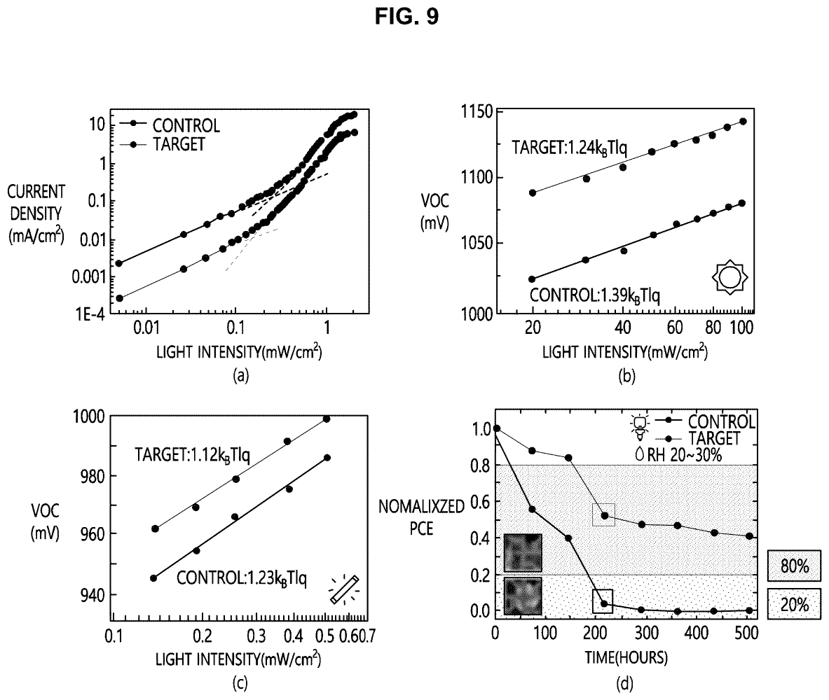

FIG. 1 is a diagram illustrating an indoor photovoltaic cell structure according to an embodiment of the present invention, FIG. 2 is a view illustrating a scanning electron microscope photograph of the perovskite quantum dot-based indoor photovoltaic cell according to an embodiment of the present invention, FIG. 3 is a schematic diagram of a perovskite quantum dot surface according to an embodiment of the present invention, FIG. 4 and FIG. 5 are a diagram illustrating FT-IR analysis results, X-ray rotation analysis results, absorbance, emission spectrum, and time-resolved fluorescence spectroscopy results before and after surface passivation according to an embodiment of the present invention, FIG. 6 and FIG. 7 are a diagram illustrating the results of highest efficiency of indoor photovoltaic cell performance specified in outdoor lighting depending on whether the surface passivation is performed on the perovskite quantum dot according to an embodiment of the present invention, the results of highest efficiency of indoor photovoltaic cell performance in indoor lighting, and external quantum efficiency (EQE) spectrum results, and FIG. 8 and FIG. 9 are a diagram illustrating the relationship between photocurrent density (Jₚₕ) and effective voltage (V_{eff}) according to outdoor and indoor light irradiation environments depending on whether the surface passivation is performed on the perovskite quantum dot surface according to an embodiment of the present invention, electrochemical impedance spectroscopy (EIS) measurement results, space charge limit current analysis results, and results of analyzing changes in V_{OC} according to light intensity in outdoor and indoor light irradiation environments and analyzing changes in safety of an indoor photovoltaic cell.

As illustrated in FIG. 1, an indoor photovoltaic cell 100 is configured to include a lower electrode layer 110, an electron transport layer 120, a photoactive layer 130, a charge transport layer 140, and an upper electrode layer 150 that are formed on a transparent substrate.

The lower electrode layer 110 is formed on the transparent substrate, and may transmit light and allow current to flow. For example, the lower electrode layer 110 may be formed of a transparent conductive oxide, and may be fluorine-doped tin oxide (FTO). The description will focus on the assumption that the lower electrode layer 110 is FTO, but the lower electrode layer 110 is not limited to the FTO.

The electron transport layer 120 is a layer through which electrons move, and may be formed on the lower electrode layer 110. The electron transport layer 120 may serve to transport electrons separated from the photoactive layer 130 to the lower electrode layer 110. The electron transport layer 120 may be formed of, for example, TiO₂ nanoparticles. This electron transport layer 120 may be formed by spin coating TiO₂ nanoparticles.

The photoactive layer 130 may be formed on the electron transport layer 120. For example, the photoactive layer 130 may be formed of quantum dots (hereinafter referred to as perovskite quantum dots) including a perovskite structure compound. Here, the perovskite quantum dots may be formed using a layer by layer (LBL) deposition method. The perovskite quantum dots may be manufactured into a thin film of a predetermined thickness using the LBL deposition method.

The description will be made with reference to FIG. 3.

The perovskite quantum dots may be manufactured into the thin film by depositing them to a predetermined thickness using the LBL deposition method. The perovskite quantum dot formed in this way has limited charge transfer problems due to a long-chain insulating ligand remaining on the surface. Accordingly, according to an embodiment of the present invention, a surface passivation process may be performed to replace a long-chain insulating organic ligand on the surface of the perovskite quantum dot with 2-(9H-carbazol-9-yl)ethyl phosphate (2PACz) which is an organic ligand conjugated with a short chain.

The charge transport layer 140 is formed on the photoactive layer 130. For example, the charge transport layer 140 may be formed of Spiro-OMeTAD.

The upper electrode layer 150 is formed on the charge transport layer 140. For example, the upper electrode layer 150 may be formed of MoO₃/Ag. For example, the upper electrode layer 150 may be an Ag layer with a thickness of 150 nm formed through a shadow mask in a thermal evaporator under a vacuum of 8×10⁻⁸ torr.

FIG. 2 illustrates a scanning electron microscope photo of the perovskite quantum dot-based indoor photovoltaic cell.

The operating principle of the perovskite quantum dot-based indoor photovoltaic cell is as follows.

(1) light absorption, (2) exciton generation, (3) exciton movement, (4) exciton positive and negative charge separation, and (5) charge absorption of an electrode.

Among the operating principles of an indoor photovoltaic cell, positive and negative charges generated by light move to electrodes at both ends according to a work function of the charge transport layer. The photoactive layer 130 absorbs light to generate excitons, and the excitons induced by indoor light may diffuse, move to each electrode, and are then collected in the form of positive and negative charges to generate electricity.

FIG. 3 is a schematic diagram of a perovskite quantum dot surface according to an embodiment of the present invention.

FIG. 4 and FIG. 5 are a diagram illustrating FT-IR analysis results, X-ray rotation analysis results, absorbance, emission spectrum, and time-resolved fluorescence spectroscopy results before and after surface passivation according to an embodiment of the present invention.

FIG. 4(a) illustrates the results of Fourier transform infrared spectroscopy (FT-IR) analysis of the perovskite quantum dot thin film before and after the surface passivation, which demonstrates that the 2PACz exists in combination with the thin film.

In addition, FIG. 4(b) illustrates the results of X-ray diffraction analysis of the perovskite quantum dot thin film before and after surface passivation. It can be seen that there is no change in crystallinity of the perovskite quantum dot before and after the surface passivation. It can be seen that even if the surface passivation is performed using the 2PACz on the perovskite quantum dot thin film, there is no damage to the perovskite quantum dot.

FIGS. 5(a) and 5(b) are the results of analyzing the absorption and emission of the perovskite quantum dot thin film before and after the surface passivation. A red shift is observed after the surface passivation due to the ligand change on the surface of the perovskite quantum dot.

FIG. 5(c) illustrates time-resolved fluorescence spectroscopy results of the thin film before and after the surface passivation, which demonstrates that the lifespan of charge carriers increases and the charge transport is improved after the surface passivation.

In an embodiment of the present invention, in order to confirm the improvement in the performance of the indoor photovoltaic cell due to the effective increase in the charge life and the minimization of defects, the performance was evaluated under solar conditions (Air mass 1.5 global, AM1.5G) and indoor light sources (LED, FL) at 1000 lux, and the results are shown in FIG. 6 and FIG. 7

FIG. 6(a) is a diagram illustrating the results of the highest efficiency of indoor photovoltaic cell performance specified under outdoor lighting, FIG. 6(b) is a diagram illustrating the results of the highest efficiency of indoor photovoltaic cell performance under indoor lighting, and FIG. 7 is a diagram illustrating an external quantum efficiency (EQE) spectrum.

TABLE 1

| | V_{OC} | J_{SC} | FF | PCE |
|---|---|---|---|---|
| Device | (mV) | (mA/cm²) | (%) | (%) |
| Control | 1075 ± 23 | 15.5 ± 0.3 | 68.3 ± 2.4 | 11.4 ± 0.6 |
| Target | 1135 ± 21 | 15.7 ± 0.4 | 73.2 ± 1.8 | 13.0 ± 0.5 |

As illustrated in FIG. 6(a) and Table 1, it can be seen that the photoelectric conversion efficiency (PCE) has increased through improvements in an open circuit voltage V_{oc} and a filling factor FF.

TABLE 2

| | V_{OC} | J_{SC} | FF | PCE |
|---|---|---|---|---|
| Device | (mV) | (μA/cm²) | (%) | (%) |
| Control | 968 ± 6 | 156.0 ± 3.9 | 73.5 ± 1.6 | 36.8 ± 0.9 |
| Target | 984 ± 8 | 160.3 ± 1.6 | 76.7 ± 1.0 | 40.3 ± 0.6 |

As illustrated in FIG. 6(b) and Table 2, it can be seen that the photoelectric conversion efficiency (PCE) has increased through improvements in the open circuit voltage V_{oc} and the filling factor FF.

The improvement in V_{OC} and FF due to the surface passivation in the outdoor and indoor light environments is the result of the increase in lifespan of the charge carrier and the improvement in the charge transport.

FIG. 7 illustrates the EQE spectrum of each device, and the device with the perovskite quantum dot thin film on which the surface passivation is performed shows a higher EQE, which is consistent with the current density of the J-V characteristic curve.

FIGS. 8(a) and 8(b) are diagrams showing the relationship between photocurrent density (Jₚₕ) and effective voltage (V_{eff}) according to the outdoor and indoor light irradiation environments, respectively.

The indoor photovoltaic cell in which the surface passivation is not performed on the perovskite quantum dot thin film showed saturation of V_{eff} at 0.37V and 0.19V in the outdoor and indoor light environments, respectively, and the indoor photovoltaic cell on which the passivation is performed showed saturation of Jₚₕ at 0.23V and 0.14V in the outdoor and indoor light environments.

The significant difference in V_{eff} values is a result of the lower dependence on the electric field through the surface passivation of the perovskite quantum dot thin film. When performing the surface passivation of the perovskite quantum dot thin film, it can be seen that the FF is improved in the photovoltaic cell due to the fewer trap state and excellent charge transport.

FIG. 8(c) is the result of confirming the Nyquist plot through electrochemical impedance spectroscopy (EIS) measurement to further characterize the recombination of the charge carrier. The recombination resistance R_{rec} based on a semicircle diameter is 175.79 kΩ for the indoor photovoltaic cell in which the surface passivation is not performed on the perovskite quantum dot thin film, and 235.74 kΩ for the indoor photovoltaic cell in which the surface passivation is performed on the perovskite quantum dot thin film. As the R_{rec} value is significantly higher, the charge recombination is strongly suppressed, and it can be seen that the charge recombination is suppressed when the surface passivation of the perovskite quantum dot thin film is performed as in an embodiment of the present invention.

FIG. 8(d) illustrates the result of space-charge-limited current (SCLC) analysis to confirm the reduction of the trap state through the surface passivation of the perovskite quantum dot thin film. Each hole-only device was manufactured with or without the surface passivation of the perovskite quantum dot thin film, and the J-V characteristics were confirmed in the dark state.

The trap state density of the hole is calculated as 2.52×1016/cm³ in the device in which the surface passivation of the perovskite quantum dot thin film is not performed, and 1.77×1016/cm³ in the device in which the surface passivation of the perovskite quantum dot thin film is performed, so the decrease in trap state was confirmed.

FIGS. 9(a) and 9(b) are diagrams illustrating changes in V_{OC} according to light intensity in the outdoor and indoor light (LED) irradiation environments, respectively. The closer the ideality factor according to the light intensity is to 1, the more ideal it is. In the outdoor light, the ideality factors of the indoor photovoltaic cell in which the surface passivation of the perovskite quantum dot thin film is not performed and the indoor photovoltaic cell in which the surface passivation of the perovskite quantum dot thin film is performed are 1.39 and 1.27, respectively, and in the indoor light, the ideality factors are 1.23 and 1.12, respectively. As a result, it can be seen that the surface passivation of the perovskite quantum dot thin film using 2PACz may reduce potential losses by reducing the trap-assisted recombination losses.

FIG. 9(c) illustrates the results of comparing the changes in stability of the photovoltaic cell according to the surface passivation using 2PACz on the perovskite quantum dot thin film at a relative humidity of 20-30%. In the case of the photovoltaic cell in which the surface passivation was not performed on the perovskite quantum dot thin film, when 144 hours after manufacturing has elapsed, the initial efficiency was 40%, and when 216 hours after manufacturing has elapsed, the perovskite quantum dot changes to the non-photoactive phase, which appeared less than 1% of the initial efficiency.

On the other hand, in the case of the indoor photovoltaic cell in which the surface passivation is performed on the perovskite quantum dot thin film, when 144 hours after the manufacturing have elapsed, the photovoltaic cell in which the surface passivation was performed was maintained more than 80% of the initial efficiency, and when 500 hours after the manufacturing have elapsed, maintained more than 40% of the initial efficiency. This is the result of improving the moisture stability of the perovskite quantum dots because the carbazole functional group of 2PACz is hydrophobic.

Embodiments of the present invention have been mainly described hereinabove. It will be understood by those skilled in the art to which the present invention pertains that the present invention may be implemented in a modified form without departing from essential characteristics of the present invention. Therefore, embodiments disclosed herein should be considered in an illustrative aspect rather than a restrictive aspect. The scope of the present invention should be defined by the claims rather than the above description, and all differences within the scope equivalent to the claims should be interpreted to fall within the present invention.

What is claimed is:

1. An indoor photovoltaic cell, comprising:
a transparent lower electrode layer through which indoor light passes;
a photoactive layer that generates excitons by the indoor light and separates the excitons into positive and negative charges; and
an upper electrode layer that absorbs the negative charge,
wherein the photoactive layer is formed of a perovskite quantum dot.

2. The indoor photovoltaic cell of claim 1, wherein the photoactive layer is formed by forming the perovskite quantum dot into a thin film of a predetermined thickness using an LBL deposition method and then performing a surface passivation process.

3. The indoor photovoltaic cell of claim 2, wherein a surface passivation process is performed to replace a long-chain insulating organic ligand on the surface of the perovskite quantum dot with 2-(9H-carbazol-9-yl)ethyl phosphate (2PACz) conjugated with a short chain.

4. The indoor photovoltaic cell of claim 1, further comprising:
a charge transport layer between the photoactive layer and the upper electrode layer,
wherein the charge transport layer is formed of Spiro-OMeTAD.

5. A method of manufacturing an indoor photovoltaic cell, comprising:
(a) forming a transparent lower electrode through which indoor light passes on a substrate;
(b) generating excitons by the indoor light by depositing a perovskite quantum dot on a transparent lower electrode to a predetermined thickness using an LBL deposition method, and forming a photoactive layer separating the excitons into positive and negative charges; and
(c) forming an upper electrode layer on the photoactive layer to absorb the negative charge,
wherein, in the step (b), the perovskite quantum dots are deposited to the predetermined thickness, and then a surface passivation process is performed to form the photoactive layer.
